(19) United States
(12) Patent Application Publication
(10) Pub. No.: US 2008/0017940 A1
(43) Pub. Date: Jan. 24, 2008

(54) IMAGE SENSING MODULE

(76) Inventor: Cheng-Chieh Yang, Taipei City (TW)

Correspondence Address: NORTH AMERICA INTELLECTUAL PROPERTY CORPORATION, P.O. BOX 506, MERRIFIELD, VA, 22116, US

(21) Appl. No.: 11/458,103

(22) Filed: Jul. 18, 2006

(51) Int. Cl. H01L 27/00

(52) U.S. Cl. 257/432; 250/208.1; 257/433; 257/E31.127

(57) ABSTRACT

An image sensing module includes an image sensor chip. The image sensor chip has a first surface and an image sensing area on the first surface, where the image sensing area is utilized for sensing light rays illuminating thereon. The image sensor chip includes a plurality of input/output (I/O) terminals and a plurality of power/ground terminals outside the image sensing area on the first surface, where the I/O terminals are utilized for inputting/outputting signals. The image sensing module further includes a printed circuit board (PCB) having a first surface opposite the first surface of the image sensor chip and having an opening corresponding to the image sensing area, where the image sensing area is aligned within the opening. The image sensing module further includes a light transmissible cover bonded to a second surface of the PCB for covering the opening to protect the image sensing area.

### BACKGROUND OF THE INVENTION

1. Field of the Invention

The present invention relates to chip packaging, and more particularly, to an image sensing module comprising an image sensor chip.

2. Description of the Prior Art

Please refer to FIG. 1. FIG. 1 illustrates a packaging structure for an image sensor chip 73 according to the prior art. The image sensor chip 73 is bonded to an upper surface of a carrier substrate 71, whose lower surface has a plurality of terminal contacts 72 thereon. The terminal contacts 72 typically comprise metal bumps or balls. A plurality of terminal contacts 77 on the upper surface of the carrier substrate 71 are utilized for coupling input/output (I/O) terminals and power/ground terminals of the image sensor chip 73 through a plurality of wires 78, where the terminal contacts 77 on the upper surface are electrically connected to the terminal contacts 72 on the lower surface, respectively. As shown in FIG. 1, the image sensor chip 73 is surrounded by a plurality of protective barriers 75 that are covered by a transparent lid 74. Therefore, the image sensor chip 73 is encapsulated by the closed space formed by the carrier substrate 71, the protective barriers 75, and the transparent lid 74. Please note that the packaging structure shown in FIG. 1 usually occupies too much space of a circuit comprising the packaging structure. In addition, the processes respectively for forming the protective barriers 75 and the wires 78 are cost-ineffective.

Please refer to FIG. 2. FIG. 2 illustrates another packaging structure for an image sensor chip 81 according to the prior art. The image sensor chip 81 is bounded to a transparent substrate 82 by utilizing a flip-chip process, and then packed by utilizing a semiconductor process, where a plurality of terminal contacts 83 comprising metal bumps or balls are formed on a lower side of the packaging structure as shown in FIG. 2. The packaging structure shown in FIG. 2 is proposed to package a plurality of image sensor chips of the same wafer at the same time, so the workflow for packaging the image sensor chips would probably be cost-effective. However, packaging damaged image sensor chips is unnecessary. In addition, if the yield rate of the image sensor chips is not high enough, the cost of packaging the damaged image sensor chips might not be covered.

According to the prior art, the processes respectively for packaging the image sensor chip 73 and the image sensor chip 81 are complicated. Additionally, it is not easy to control the yield rates of packaging the image sensor chip 73 and packaging the image sensor chip 81. Therefore, it is almost an unachievable goal to further reduce the packaging costs according to the prior art.

### SUMMARY OF THE INVENTION

It is an objective of the claimed invention to provide image sensing modules to solve the above-mentioned problem.

It is another objective of the claimed invention to provide image sensing modules, to achieve lower packaging costs in contrast to the prior art.

According to one embodiment of the claimed invention, an image sensing module is disclosed. The image sensing module comprises an image sensor chip. The image sensor chip has a first surface and an image sensing area on the first surface, where the image sensing area is utilized for sensing light rays illuminating thereon. In addition, the image sensor chip comprises a plurality of input/output (I/O) terminals and a plurality of power/ground terminals outside the image sensing area on the first surface, where the I/O terminals are utilized for inputting/outputting signals. The image sensing module further comprises a printed circuit board (PCB) having a first surface opposite the first surface of the image sensor chip and having an opening corresponding to the image sensing area, where the image sensing area is aligned within the opening. Additionally, the PCB comprises a plurality of I/O terminals and a plurality of power/ground terminals respectively corresponding to the I/O terminals and the power/ground terminals of the image sensor chip, where the I/O terminals and the power/ground terminals of the PCB are utilized as I/O terminals and power/ground terminals of the image sensing module. The PCB further comprises a plurality of conducting wires respectively coupling between the I/O and power/ground terminals of the PCB and the I/O and power/ground terminals of the image sensor chip, where each of the conducting wires has a first end on the first surface of the PCB for coupling one of the I/O terminals and the power/ground terminals of the image sensor chip. The image sensing module further comprises a light transmissible cover bonded to a second surface of the PCB for covering the opening to protect the image sensing area.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a packaging structure for an image sensor chip according to the prior art.

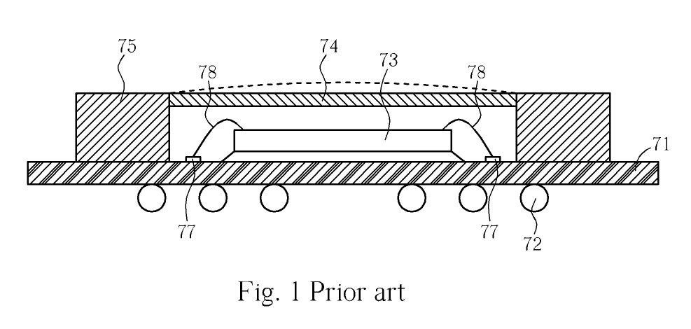

FIG. 2 illustrates another packaging structure for an image sensor chip according to the prior art.

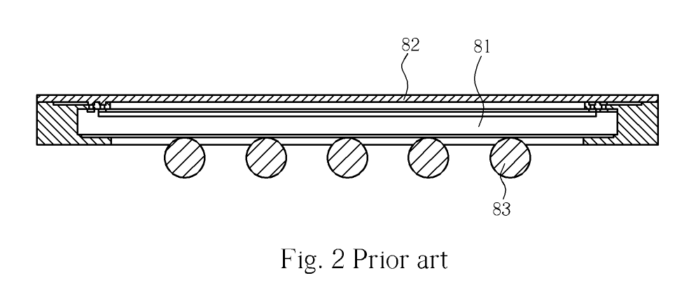

FIG. 3 is a cross-section view of an image sensing module according to one embodiment of the present invention.

### DETAILED DESCRIPTION

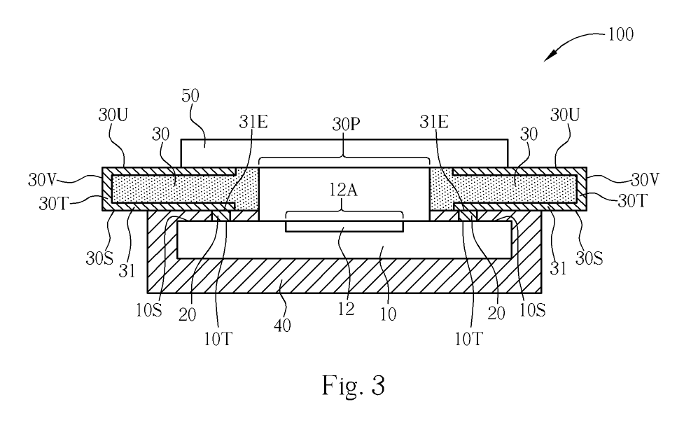

Please refer to FIG. 3. FIG. 3 illustrates an image sensing module 100 according to one embodiment of the present invention, where the image sensing module 100 comprises an image sensor chip 10, a plurality of flip chip joints 20, a printed circuit board (PCB) 30, a protective shell 40, and a light transmissible cover 50. According to the present invention, the PCB for implementing the image sensing module can be a multi-layer PCB or a single-layer PCB. In this embodiment, the PCB 30 is a multi-layer PCB.

The image sensor chip 10 has a first surface 10S (which is the upper surface of the image sensor chip 10 according to FIG. 3) and an image sensing area 12A on the first surface 10S, where a sensor array region 12 is illustrated as a representative of sensor arrays of the image sensing area 12A in the cross-section view of the image sensing module 100 shown in FIG. 3. The image sensing area 12A is utilized for sensing light rays illuminating thereon. According to this embodiment, the image sensor chip 10 is a charge coupled device (CCD) sensor chip, and the sensor arrays are CCD arrays. It is noted that according to another embodiment of the present invention, the image sensor chip 10 can be a CMOS sensor chip.

The image sensor chip 10 comprises a plurality of input/output (I/O) terminals and a plurality of power/ground terminals outside the image sensing area 12A on the first surface 10S, where these terminals of the image sensor chip 10 are referred to as the terminals 10T for simplicity in this embodiment. The terminals 10T are electrically connected to the flip chip joints 20, respectively, where the I/O terminals mentioned above are utilized for inputting/outputting signals, and the power/ground terminals are utilized for power transmission and grounding. In addition, the PCB 30 has a first surface 30S (which is the lower surface of the PCB 30 according to FIG. 3) opposite the first surface 10S of the image sensor chip 10 and has an opening 30P corresponding to the image sensing area 12A, where the image sensing area 12A is aligned within the opening 30P. According to this embodiment, the opening 30P is larger than the image sensing area 12A but smaller than the first surface 10S of the image sensor chip 10, as shown in FIG. 3.

The PCB 30 comprises a plurality of I/O terminals and a plurality of power/ground terminals respectively corresponding to the I/O terminals and the power/ground terminals of the image sensor chip 10, where these terminals of the PCB 30 are referred to as the terminals 30T for simplicity in this embodiment. The I/O terminals and the power/ground terminals of the PCB 30 are utilized as I/O terminals and power/ground terminals of the image sensing module 100. The PCB 30 further comprises a plurality of conducting wires 31 respectively coupling between the terminals 30T of the PCB 30 and the terminals 10T of the image sensor chip 10, where each of the conducting wires 31 has a first end 31E on the first surface 30S of the PCB 30 for coupling one of the terminals 10T of the image sensor chip 10. As shown in FIG. 3, the first ends 31E of the conducting wires 31 are respectively coupled to the terminals 10T of the image sensor chip 10 through the flip chip joints 20. As a result, the terminals 30T of the PCB 30 are respectively coupled to the terminals 10T of the image sensor chip 10. More specifically in this embodiment, the terminals 30T of the PCB 30 are respectively electrically connected to the terminals 10T of the image sensor chip 10. Therefore, each of the terminals 30T represents one of the terminals 10T of the image sensor chip 10. According to this embodiment, each of the terminals 30T is positioned around the first surface 30S and one of the vertical surfaces 30V of the PCB 30, and even extended to a second surface 30U (which is the upper surface of the PCB 30 according to FIG. 3) for flexibility of further mounting the image sensing module 100 onto a device utilizing the image sensing module 100.

The light transmissible cover 50 is bonded to the second surface 30U of the PCB 30 for covering the opening 30P to protect the image sensing area 12A. According to the present invention, the light transmissible cover 50 may comprise a glass plate, acrylic plate, or an epoxy resin plate. According to this embodiment, the light transmissible cover 50 comprises a glass plate.

In this embodiment, the PCB 30 is a portion of a large PCB for packaging a plurality of image sensor chips such as the image sensor chip 10 to form a plurality of image sensing modules such as the image sensing module 100. The large PCB comprises a plurality of portions to be separated by cutting the large PCB, where the portions respectively have openings such as the opening 30P, and each of the portions of the large PCB comprises terminals (such as the terminals 30T) and conducting wires (such as the conducting wires 31) corresponding to one of the image sensor chips to be packaged.

According to one implementation choice of this embodiment, by utilizing a flip chip process, the image sensor chips are first bonded to the portions of the large PCB, respectively, with the image sensing area of each image sensor chip being aligned within the opening of the corresponding portion of the large PCB. Then, a plurality of light transmissible covers (such as the light transmissible cover 50) are bonded to the portions of the large PCB to cover the openings of the corresponding portions of the large PCB, respectively. As a result, the image sensor chips are packaged to form the image sensing modules, while the portions of the large PCB are finally separated.

According to another implementation choice of this embodiment, the light transmissible covers (such as the light transmissible cover 50) are first bonded to the portions of the large PCB to cover the openings of the corresponding portions of the large PCB, respectively. Then, the image sensor chips are respectively bonded to the portions of the large PCB by utilizing the flip chip process, with the image sensing area of each image sensor chip being aligned within the opening of the corresponding portion of the large PCB. As a result, the image sensor chips are packaged to form the image sensing modules, while the portions of the large PCB are finally separated.

According to different implementation choices of the flip chip process, the flip chip joints may comprise solder bumps, Au-bumps, or Au/Ni-bumps. In addition, during the flip chip process, a filling material is applied to the gap between the first surface 30S of the PCB 30 and the first surface 10S of the image sensor chip 10. According to this embodiment, other surfaces of the image sensor chip 10 are covered with the same material as the filling material mentioned above, to form the protective shell 40 of the image sensing module 100 as shown in FIG. 3.

According to one implementation choice of the flip chip process, the filling material can be an anisotropic conductive paste (ACP) or non-conductive paste (NCP). According to another implementation choice of the flip chip process, the filling material is an anisotropic conductive film (ACF) or non-conductive film (NCF). Yet according to another implementation choice of the flip chip process, the filling material is a thermosetting adhesive or UV adhesive formed by dispensing.

According to a variation of this embodiment, the light transmissible cover 50 may comprise at least one optical filter. For example, the light transmissible cover 50 comprises an infrared cut filter (IR-cut filter) for blocking at least a portion of IR light rays, and further comprises an optical low pass filter (OLPF) for performing low pass filtering to reduce or remove moire patterns that would probably exist in an image generated according to at least one signal outputted from the image sensing module 100.

According to another variation of this embodiment, the light transmissible cover 50 further comprises a lens, whereby the light rays illuminating on the image sensing area 12A form an image.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An image sensing module comprising:
an image sensor chip having a first surface and an image sensing area on the first surface, the image sensing area being utilized for sensing light rays illuminating thereon, the image sensor chip comprising a plurality of input/output (I/O) terminals and a plurality of power/ground terminals outside the image sensing area on the first surface, the I/O terminals being utilized for inputting/outputting signals;
a printed circuit board (PCB) having a first surface opposite the first surface of the image sensor chip and having an opening corresponding to the image sensing area, the image sensing area being aligned within the opening, the PCB comprising:
a plurality of I/O terminals and a plurality of power/ground terminals respectively corresponding to the I/O terminals and the power/ground terminals of the image sensor chip, wherein the I/O terminals and the power/ground terminals of the PCB are utilized as I/O terminals and power/ground terminals of the image sensing module; and
a plurality of conducting wires respectively coupling between the I/O and power/ground terminals of the PCB and the I/O and power/ground terminals of the image sensor chip, wherein each of the conducting wires has a first end on the first surface of the PCB for coupling one of the I/O terminals and the power/ground terminals of the image sensor chip; and
a light transmissible cover bonded to a second surface of the PCB for covering the opening to protect the image sensing area.

2. The image sensing module of claim 1, further comprising:
a plurality of flip chip joints;
wherein the first ends of the conducting wires are respectively coupled to the I/O terminals and the power/ground terminals of the image sensor chip through the flip chip joints.

3. The image sensing module of claim 2, wherein the flip chip joints comprise solder bumps, Au-bumps, or Au/Ni-bumps.

4. The image sensing module of claim 2, wherein the opening is larger than the image sensing area but smaller than the first surface of the image sensor chip.

5. The image sensing module of claim 4, further comprising:
a filling material applied to the gap between the first surface of the PCB and the first surface of the image sensor chip.

6. The image sensing module of claim 5, wherein other surfaces of the image sensor chip are covered with the same material as the filling material.

7. The image sensing module of claim 5, wherein the filling material is an anisotropic conductive paste (ACP) or non-conductive paste (NCP).

8. The image sensing module of claim 5, wherein the filling material is an anisotropic conductive film (ACF) or non-conductive film (NCF).

9. The image sensing module of claim 5, wherein the filling material is a thermosetting adhesive or UV adhesive formed by dispensing.

10. The image sensing module of claim 1, wherein the light transmissible cover comprises at least one optical filter.

11. The image sensing module of claim 10, wherein the light transmissible cover comprises an infrared cut filter (IR-cut filter) for blocking at least a portion of IR light rays.

12. The image sensing module of claim 10, wherein the light transmissible cover comprises an optical low pass filter (OLPF) for performing low pass filtering to reduce or remove moire patterns that would probably exist in an image generated according to at least one signal outputted from the image sensing module.

13. The image sensing module of claim 1, wherein the light transmissible cover comprises a glass plate, acrylic plate, or an epoxy resin plate.

14. The image sensing module of claim 1, wherein the PCB is a multi-layer PCB.

15. The image sensing module of claim 1, wherein the PCB is a single-layer PCB.

16. The image sensing module of claim 1, wherein the light transmissible cover comprises a lens, whereby the light rays illuminating on the image sensing area form an image.
